(19) United States
(12) Patent Application Publication
(10) Pub. No.: US 2014/0269054 A1
(43) Pub. Date: Sep. 18, 2014

(54) NON-VOLATILE MEMORY AND METHOD OF OPERATION THEREOF

(71) Applicant: MACRONIX INTERNATIONAL CO., LTD., Hsin-Chu City (TW)

(72) Inventors: GUAN WEI WU, KAOHSIUNG COUNTY (TW); YAO WEN CHANG, HSINCHU CITY (TW); I CHEN YANG, CHANGHUA COUNTY (TW); TAO CHENG LU, HSINCHU (TW)

(73) Assignee: Macronix International Co., Ltd., Hsin-Chu City (TW)

(21) Appl. No.: 13/855,989

(22) Filed: Apr. 3, 2013

Related U.S. Application Data
(60) Provisional application No. 61/778,338, filed on Mar. 12, 2013.

(51) Int. Cl. G11C 16/34

(52) U.S. Cl. CPC G11C 16/34
USPC 365/185.03

(57) ABSTRACT

A method of altering threshold voltage distribution of a non-volatile MLC memory before the memory is programmed according to a pre-designated coding table. The method includes grouping a plurality of cells which are pre-designated to have the same first bit voltage in a same main state and then grouping the cells in a selected main state into a same sub state if they have the same pre-designated second bit voltage. The method further has a step by elevating the first bit voltage of the cells with highest pre-designated second bit voltage to a voltage which is greater than the voltage of the pre-designated highest main state.

### CROSS-REFERENCE TO RELATED APPLICATION

This application claims the priority benefit of U.S. provisional application Ser. No. 61/778,338, filed on Mar. 12, 2013. The entirety of the above-mentioned patent application is hereby incorporated by reference herein and made a part of this specification.

### FIELD OF THE INVENTION

The present invention relates in general to a method of operating a non-volatile memory cell, and more particularly to a multi-level cell (MLC) nonvolatile memory.

### BACKGROUND

The capacity of non-volatile memory has increased more than hundred times as a result of aggressive process scaling and multi-level cell (MLC) technology. The basic method used in MLC technology is similar with binary-level cell (BLC), except that it enables multiply the number of bits to be stored in a single cell by charging to different voltage levels instead of two. Typically, a MLC can be designed to store 2ⁿ (n>1) voltage levels by using 2ⁿ−1 threshold voltage (Vₜ) levels to distinguish between 2ⁿ states. FIG. 1 illustrates an ideal Vₜ level placement for a two bits per cell MLC. The logic value a cell stores is determined by the voltage window in which the cell's threshold voltage lies.

However, in reality, as cell size is scaled down and more bits per cell are stored, the threshold voltage window used to represent each value becomes narrower than the BLC cell. Since both BLC and MLC-based devices may use the same size voltage window, the distance between adjacent voltage levels in MLC is much smaller than in BLC. Additionally, other factors such as process deviation, program disturb, or second bit effect may shift or widen the threshold voltage distribution, thus the distance becomes even smaller for distinguishing different states.

FIG. 2 illustrates a threshold voltage distribution of a conventional two-bit MLC non-volatile memory whereas the programmed cells can be classified into four main states 1, 2, 3, and 4 in accordance to the threshold voltage of the first bit. Each main state is composed of four different sub states n1, n2, n3, and n4 based on the second bit's threshold voltage. Typically, the first main state 1, which has the lowest threshold voltage, is most vulnerable to the disturbance and difficult to make its distribution more convergent. Hence, a portion of the first main state 1 may overlap the second main state 2. Apparently, detecting the voltage levels in an MLC cell is a more complex task than in a BLC cell. It would be necessary to reduce the error rates in determining a cell's value.

### SUMMARY OF THE INVENTION

A method of altering threshold voltage distribution of a non-volatile MLC memory before the memory is programmed according to a pre-designated coding table. The method includes grouping a plurality of cells which are pre-designated to have the same first bit voltage in a same main state and then grouping the cells in a selected main state into a same sub state if they have the same pre-designated second bit voltage. The method further has a step by elevating the first bit voltage of the cells with highest pre-designated second bit voltage to a voltage which is greater than the voltage of the pre-designated highest main state.

According to present invention, it further discloses a method of enlarging the threshold voltage window for a non-volatile MLC memory. The method includes obtaining a to-be-programmed voltage of each cell according to a pre-designated coding table, and selecting a plurality of cells wherein the cells have the same first bit voltage. The method further has step of discriminating the selected cells in accordance with each cell's second bit voltage; and step of elevating the first bit voltage of the cells with highest second bit voltage to a higher voltage. Therefore, the threshold voltage of cells with different first bit voltage is not overlapped after elevating the first bit voltage.

### BRIEF DESCRIPTION OF THE DRAWINGS

The invention will be described according to the appended drawings in which:

FIG. 1 illustrates an ideal Vₜ level placement for a two bits per cell MLC;

FIG. 2 illustrates a threshold voltage distribution of a conventional two-bit MLC non-volatile memory;

FIG. 3 illustrates a two bit non-volatile memory array;

FIG. 4 illustrates a distribution of threshold voltage of a MLC non-volatile memory with n main states;

FIG. 5 illustrates the threshold voltage distribution according to one embodiment;

FIG. 6 illustrates the threshold voltage distribution according to another embodiment;

FIG. 7 illustrates a process flow according to one embodiment;

FIG. 8 illustrates a process flow according to another embodiment;

FIG. 9A-9C illustrate the threshold voltage distribution according to one embodiment.

### DETAILED DESCRIPTION OF THE INVENTION

A description of embodiments and methods of the present invention is provided with reference to FIG. 3-9. It is to be understood that there is no intention to to limit the invention to the specifically disclosed embodiments but that the invention can be practiced using other features, elements, methods and embodiments.

FIG. 3 shows a two bit non-volatile memory array having a plurality unit memory cells 305. Each cell 305 includes a left storage 305-1 and a right storage 305-2, therein accommodating the trapped charges. The left storage 305-1 is referred as the first bit and the right storage 305-2 is referred as the second bit. According to the invention, a unit cell may include more than two bits but a two bit cell is used exemplarily in the description. Each cell 305 can be programmed to a different threshold voltage dependant on the amount of trapped charge in the storages. Typically, cells with the same first bit threshold voltage are grouped in the same main state. Further, the cells in the same main state can be discriminated into different sub states based on the second bit threshold voltage.

FIG. 4 illustrates a distribution of threshold voltage of a MLC non-volatile memory with n main states in accordance to a pre-designated coding table. The distribution of the first main state 1 has an upper bound voltage V₁_{_{—}}_{U} and a lower bound voltage V₁_{_{—}}_{L}. The first main state 1 includes i sub states and each sub state is referred as sub state 1i or 1[i] in the present disclosure. The sub states are arranged in an order from 1 to i in accordance to each sub state's upper bound voltage as from low to high. The first sub state, 11 or 1[1], has the smallest lower bound voltage, V₁₁_{_{—}}_{L}, which is also the lower bond voltage of the first main state V₁_{_{—}}_{L}, i.e V₁₁_{_{—}}_{L}=V₁_{_{—}}_{L}. The iₜₕ sub state, 1i, has the highest upper bond V₁ᵢ_{_{—}}ᵤ among other sub states in the first main state 1. The upper bound voltage V₁_{_{—}}_{U} of the first main state is also the upper bound voltage of the sub state 1i, V₁ᵢ_{_{—}}_{U}. The highest main state n has an upper bound voltage Vₙ_{_{—}}_{U}, that is the highest voltage state of all the cells at the initial stage (before first program is introduced). A voltage window is defined as the gap between each main state's upper bound voltage and its rightward adjacent main state's lower bound voltage. For example, ΔV₂₋₁ represents the window between the first and the second main state.

Before programming, memory cells that were presumed to be charged to a higher sub state in a predetermined main state, such as 1i, are selected. Then the voltage of sub state 1i in the first main state 1 is elevated by charging its first bit to a higher voltage level, therefore its elevated lower bound voltage V₁ᵢ_{_{—}}_{L} is greater than the highest main state's upper bound voltage Vₙ_{_{—}}_{U}. FIG. 5 illustrates the threshold voltage distribution after elevating the highest sub state 1 i of the first main state 1 to a higher voltage level and the upper bound of the first main state 1, V₁_{_{—}}_{U} is now determined by the upper bound voltage of the i−1ₜₕ sub state, which is 1[i−1]. The gap between the first main state 1 and the second main state 2 is apparently increased with an increment of ΔV which is equal to V₁ₜ_{_{—}}_{U} minus V_{1[i-1]}_{_{—}}_{U}, and whereby the gap between the first and the second main state is widened from ΔV₂₋₁ to ΔV+ΔV₂₋₁.

To further enlarge the gap between the first main state 1 and the second main state 2, in addition to elevating the iₜₕ sub state voltage level, cells at i−1ₜₕ sub state in the main state 1 also can be elevated to a higher voltage by charging their respective first bit to a higher voltage level such that the lower bound voltage of the i−1ₜₕ sub states is higher than the highest main state's upper bound voltage Vₙ_{_{—}}_{U}, i.e. V_{1[i-1]}_{_{—}}_{L}>Vₙ_{_{—}}_{U}. The elevated sub state can be grouped altogether to form a new main state called H main state. FIG. 6 illustrates the threshold voltage distribution after moving the iₜₕ and the i−1ₜₕ sub states of the first main state 1 to a higher voltage level to form an H main state. The upper bound of the first main state 1 is now determined by the upper bound voltage of the i−2ₜₕ sub state, therefore the gap between the first main state 1 and the second main state 2 is further widened to ΔV+ΔV₂₋₁, wherein ΔV=V₁ᵢ_{_{—}}_{U}−V_{1[i-2]}_{_{—}}_{U}, and thereby making the first and second main state more distinguishable.

According to the present invention, 1 sub states in the first main state can be elevated to a voltage higher than Vₙ_{_{—}}_{U}, wherein 1≦i, based on the window required to distinguish it with its adjacent main state.

Methods to elevate sub state voltage can be also arranged for any xₜₕ main state, wherein 1≦x≦n−1.

FIG. 7 illustrates a process flow according to one embodiment. At step 200, a to-be-coded threshold voltage distribution of a non-volatile MLC memory array is obtained and the distribution is divided into a plurality of main states, in which different cells with the same first bit voltage are grouped. Each main state includes a plurality of sub states, in which different cells with the same first bit voltage but different second bit voltage are grouped. At step 300, a main state is selected. At step 400, the highest sub state in the selected main state is elevated to a higher voltage level which surpasses the last main state and forms a new main state H. An optional step 500 can be included to elevate the second highest sub state with the highest sub state in the selected main state, then be grouped into the newly formed main state H.

FIG. 8 illustrates another embodiment of the present invention. A step 100 is added to erase the cells in a non-volatile memory array prior to program, and followed by the same steps as shown in FIG. 7.

FIG. 9A depicts a first main state distribution C that is before programming a MLC non-volatile memory. There are n main states, in which i sub states are included. Some high level sub states, such as 1i, 1[i−1], and 1[i−2], are overlapped with the second main state 2. An erasing step is applied to remove any initially trapped charges in the localized trap charge material, such as a nitride layer or an oxide/nitride/oxide stack layer, therefore the distribution C is reshaped into a different distribution C′ as shown in FIG. 9B, wherein the first main state has a longer tail than distribution C. The lower bound voltage V₁_{_{—}}_{L} is shifted leftward and there is still at least one sub state (in this case, 1i) overlapping with the second main state 2. FIG. 9C shows a distribution C″ of the first main state 1 after following the steps in FIG. 7, wherein a plurality of higher sub states are elevated to a higher voltage surpassing the highest main state n. The gap between the first main state 1 and the second main state 2 is further increased by adding the erasing step prior to elevating the sub states 1i, and 1[i−1], hence the capability to distinguish the first and second main state is improved.

The methods and features of this invention have been sufficiently described in the above examples and descriptions. It should be understood that any modifications or changes without departing from the spirit of the invention are intended to be covered in the protection scope of the invention.

What is claimed is:

1. A method of altering threshold voltage distribution of a MLC non-volatile memory before programming according to a pre-designated coding table, the method comprising:
grouping a plurality of cells which are pre-designated to have the same first bit voltage in a same main state;
grouping the cells in a selected main state into a same sub state if they have the same pre-designated second bit voltage;
elevating the first bit voltage of the cells with highest pre-designated second bit voltage to a voltage which is greater than the voltage of the pre-designated highest main state.

2. The method of claim 1 wherein the selected main state is a first main state which has the lowest voltage level among other main states.

3. The method of claim 1 wherein there are i sub states in the selected main state and the i sub states are arranged in an order from 1 to i according to each sub state's upper bound voltage, wherein the iₜₕ sub state has the highest upper bound voltage.

4. The method of claim 3 further comprising a step of elevating the i−1ₜₕ sub state to a voltage surpassing the voltage of the pre-designated highest main state.

5. The method of claim 4 further comprising forming a new high main state which has a lower bound voltage being greater than the upper bound voltage of the pre-designated highest main state.

6. The method of claim 5 further comprising grouping the elevated iₜₕ and i−1ₜₕ sub state in the new high main state.

7. The method of claim 1 further comprising a step of elevating more than two sub states to a voltage surpassing the voltage of the pre-designated highest main state.

8. The method of claim 1 further comprising a step of erasing trapped charges in the memory before elevating the first bit voltage.

9. A method of enlarging the threshold voltage window for a MLC non-volatile memory, the method comprising:
obtaining a to-be-programmed voltage of each cell according to a pre-designated coding table;
selecting a plurality of cells wherein the cells have the same first bit voltage;
discriminating the selected cells in accordance with each cell's second bit voltage; and
elevating the first bit voltage of the cells with highest second bit voltage to a higher voltage.

10. The method of claim 9 further comprising elevating the first bit voltage of the cells with second highest second bit voltage to a higher voltage.

11. The method of claim 9 wherein the threshold voltage of a portion of the selected cells overlap with a non selected cell before elevation step.

12. The method of claim 9 wherein the elevated first bit voltage is greater than the highest first bit voltage on the pre-designated coding table.

13. The method of claim 9 further comprising erasing the memory before elevating the first bit voltage.

14. The method of claim 9 wherein the threshold voltage of cells with different first bit voltage is not overlapped after elevating the first bit voltage.
